(19) United States
(12) Patent Application Publication
(10) Pub. No.: US 2022/0222399 A1
(43) Pub. Date: Jul. 14, 2022

(54) DATA STRUCTURE, NUMERICAL CALCULATION METHOD, AND NUMERICAL CALCULATION PROGRAM

(71) Applicant: DEEPFLOW, INC., Saitama (JP)

(72) Inventor: Hiroki Fukagawa, Saitama (JP)

(73) Assignee: DEEPFLOW, INC., Saitama (JP)

(21) Appl. No.: 17/615,664

(22) PCT Filed: Aug. 2, 2019
(86) PCT No.: PCT/JP2019/030449

§ 371 Date: Dec. 1, 2021

(51) Int. Cl. G06F 30/23

(52) U.S. Cl. CPC G06F 30/23

(57) ABSTRACT

A system for calculating a shape and a plurality of physical quantities, the system comprising: a hierarchical storage; and processor circuitry that couples to the hierarchical storage and is configured to: divide, into cell complexes and dual cell complexes, a domain for which calculations are to be conducted, to correspond to the shape; assign the plurality of physical quantities to the cell complexes and the dual cell complexes; and reference data stored in the hierarchical storage by using a Hodge star operator and a boundary homomorphic that are defined for the cell complexes and dual cell complexes.

### CROSS-REFERENCE TO RELATED APPLICATION

This application is a national stage application of International Application No. PCT/JP2019/030449, filed on Aug. 2, 2019 and designated the U.S., the contents of which are herein incorporated by reference.

### FIELD

The present disclosure relates to a data structure, a numerical calculation method, and a numerical calculation program.

Generally computer-aided design (CAD) is used in the modern design process. This is because when compared to creating designs through manual operations, creating designs through the use of computers involves less work of course, and can greatly improve the efficiency of correction work and editing work as well. Moreover, digitized drawings are superior in terms of ability to share data, and can facilitate cooperative work.

On the other hand, there have also been advances in computer-aided engineering (CAE) in the research and development stage. In the research and development stage verifications are carried out regarding performance, such as strength, and the like, of many prototypes, and the use of CAE makes it possible to verify performance of large numbers of prototypes through computer simulations.

### Non-Patent Documents

Non-Patent Document 1: FUKAGAWA, Hiroki, “Fluid Structure Interaction Analysis of a Bearing using an Explicit Method,” Supercomputing News, 2018, 08, Vol. 20, No. Special Issue 2, pp. 4-9

### SUMMARY

While, as described above, CAD and CAE are used in product research, development, and design, there are several problems in sharing data between the two. This is because there is a preferred data structure for CAD and is a preferred data structure for CAE, and typically these are not the same.

For example, for use in CAE, a data structure that is made from hexahedrons, called a structured grid, is preferred. A data structure made from a structured grid is not only well-suited to numeric calculations, but also enables use of numerical calculation methods that are unique to structured grids, such as staggered grids.

A staggered grid is a technique that enhances the stability of calculations through establishing calculation points at positions where the structured grid is offset by a half period, assigning scalar values to the centers in the structured grid, and assigning vector values that are perpendicular to the surface at the centers of the surfaces of the structured grid. For example, in fluid analysis using a staggered grid, numeric calculation is carried out through assigning physical quantities for the pressures (which are scalar values) at the centers in the structured grid, and assigning physical quantities that are the flow speeds (which are vector values) at the centers of the surfaces of the structured grid.

On the other hand, CAD may require an unstructured grid. This is because only the shapes that are somewhat simple can be handled through a structured grid. Shapes with some degree of flexibility can be handled through the use of a structured grid into which cubes are converted using a technique called “mapped mesh,” which can be used in CAE as well (see Non-Patent Document 1). However, there are limitations on the use of this technique as well.

Given this, there is the need for techniques for numeric calculations that can be used with an unstructured grid as well, and one example thereof is known as the “finite volume method.” In the finite volume method, the analysis domain is divided into domains called control volumes, and a conservation equation is applied to each control volume. Given this, insofar as the control volumes do not overlap with each other, conservation is satisfied in the entirety of the analysis domain.

However, while the finite volume method may be used even with an unstructured grid, from the point of view of numerical stability, numerical calculation methods that use staggered grids are more preferable.

The present disclosure was created in contemplation of the above, and the object thereof is to provide a data structure, a numerical calculation method, and a numerical calculation program that enable calculation of numeric values with high stability, even when an unstructured grid is used

In order to solve the problem set forth above, in a data structure according to one aspect of the present disclosure a domain for which numeric values are calculated is divided into cell complexes, dual cell complexes of the cell complexes are defined, and physical quantities used in numerical calculations are assigned to the cell complexes and dual cell complexes.

Moreover, a method for numerical calculation according to one aspect of the present disclosure uses a data structure wherein a domain for which numeric values are calculated is divided into cell complexes, dual cell complexes of the cell complexes are defined, and physical quantities used in numerical calculations are assigned to the cell complexes and dual cell complexes, and that wherein the governing equations used in the aforementioned numeric calculation are converted into differential-type equations in the aforementioned cell complexes and dual cell complexes.

A numerical calculation program according to one aspect of the present disclosure is a numerical calculation program for executing numeric calculations on a computer that has a plurality of computing units and hierarchical storage units for storing data used in calculation by the computing units, including a step for dividing, into cell complexes, a domain for which the numerical calculations are to be conducted, to define dual cell complexes of the cell complexes, and for storing, in the hierarchical storage unit, physical quantities used in numerical calculations that have been assigned to the cell complexes and the dual cell complexes; and a step for using, in numeric calculations regarding physical quantities assigned to the cell complexes and the dual cell complexes, using that wherein the governing equations used in the numeric calculations have been converted to equations in differential form on the cell complexes and the dual cell complexes.

The present disclosure enables provision of a data structure, a numerical calculation method, and a numerical calculation program that enables highly stable numeric calculation using an unstructured grid.

### DRAWINGS

FIG. 1 is a diagram depicting examples of a structured grid and of unstructured grids.

FIG. 2 is a diagram depicting a complex structure of a tetrahedron.

FIG. 3 is a diagram illustrating a boundary homomorphic.

FIG. 4 is a diagram illustrating the relationship between the cell complexes and the dual cell complexes.

FIG. 5 is a diagram illustrating paired control of cell complexes and dual cell complexes.

FIG. 6 is a diagram depicting the concept of a hierarchy of a shared memory-type.

FIG. 7 is a diagram depicting the concept of a hierarchy of a distributed memory-type.

FIG. 8 is a diagram depicting the relationship between the neighborhood and dual cell.

FIG. 9 is a diagram depicting the concept of an explicit method having high reference locality.

### EMBODIMENTS

A data structure, a numerical calculation method, and a numerical calculation program according to embodiments according to the present disclosure will be explained below in reference to the drawings. However, the drawings that are referenced in the explanations below are schematic, and the dimensions and proportions therein may be different from actual embodiments.

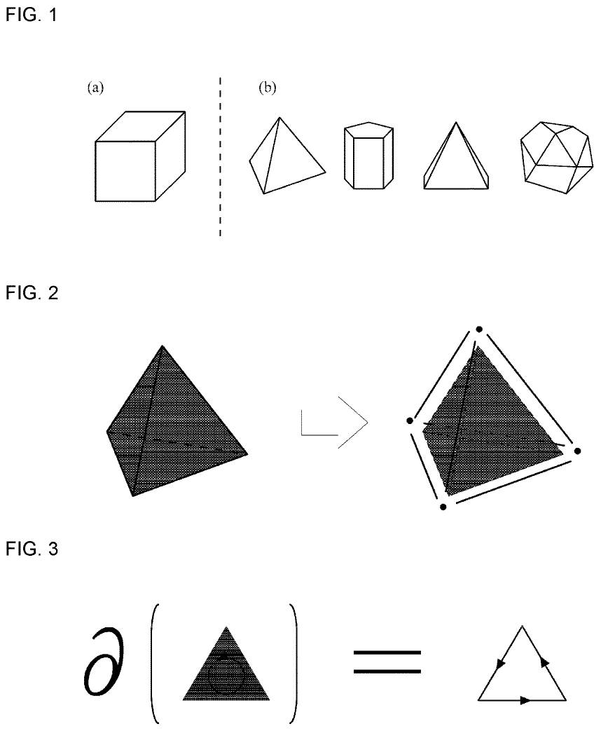

The data structure according to the present embodiment is not limited to a structured grid, but a general structured grid, which include an unstructured grid, is used. FIG. 1 is a diagram depicting examples of a structured grid and unstructured grids. A structured grid is a calculation mesh wherein a computational domain is divided using a hexahedron as an individual unit, as depicted in FIG. 1 (a). On the other hand, an unstructured grid refers to that which is other than a structured grid. Consequently, an unstructured grid is thus a calculation mesh where a computational domain is divided into an arbitrary combination of polyhedrons, including tetrahedrons and pentahedrons, as depicted in FIG. 1 (b).

Note that a “polyhedron” in the data structure according to the present embodiment is a “cell complex” referred to in the mathematical definition. That is, it is a polyhedron that has a complex structure, rather than a polyhedron that is thought of as being simply a shape. A “cell complex” refers to that wherein a unit, called a n-dimensional cell, that is a homomorphism of a k-dimensional disc, has a prescribed hierarchy. A typical polyhedron is structured from units that are homomorphic with k-dimensional discs that are surfaces or edges, where a cell complex corresponds to a generalization of a polyhedron.

For example, as in FIG. 2, a tetrahedron can be decomposed into four 0-complexes (vertices), six 1-complexes (edges), four 2-complexes (surfaces), and one 3-complex (a bulk). In the data structure according to the present embodiment, the computational domain is divided into arbitrary polyhedrons, where, in this case, the polyhedrons can be considered to have structures as complexes as described above. In other words, in the data structure according to the present embodiment the domain over which the numerical calculations are to be conducted is divided into cell complexes. Note that a hexahedron is also a polyhedron that has a complex structure. Consequently, the data structure according to the present embodiment does not exclude the use of a hexahedron as a shape, but rather allows for the use of general polyhedrons through division of the domain, over which the numerical calculations are to be conducted, into cell complexes having complex structures. Moreover, the calculations are possible even if the surfaces are curved surfaces.

Here each complex has an orientation. Here a chain homomorphic ∂ₖ: Cₖ (X)→Cₖ₋₁ (X) is defined for the chain complex for a free Abelain group Cₖ (X) that generates the oriented k-dimensional complex. FIG. 3 is a diagram depicting an example of a boundary homomorphic ∂₂: C₂ (X)→C₁ (X) from an oriented 2-complex (surface) to an oriented 1-complex (edge).

This boundary homomorphic operates, as described below, in respect to a chain complex Cₖ (X), satisfying ∂ₖ ∂ₖ₋₁=0.

$$\begin{matrix}[ Formula 1 ] & \\ 0 \to {C}_{n} ( X ) \to … \to {C}_{k} ( X ) {\to }^{\partial } {C}_{k - 1} ( X ) \to … \to {C}_{0} ( X ) \to 0 & \end{matrix}$$

On the other hand, in dividing of polyhedrons that have complex structures, dual cell complexes can be defined. Because, in normal calculation of numeric values, a divided domain for which the numerical calculations are to be conducted is termed a mesh, the dual cell complexes that are used in the data structure according to the present embodiment may be called a “dual mesh.” Note that in the data structure according to the present embodiment, the mesh for dividing the domain has not merely shapes, but structures as complexes, and similarly the dual mesh may be considered to have structures as complexes, rather than merely shapes.

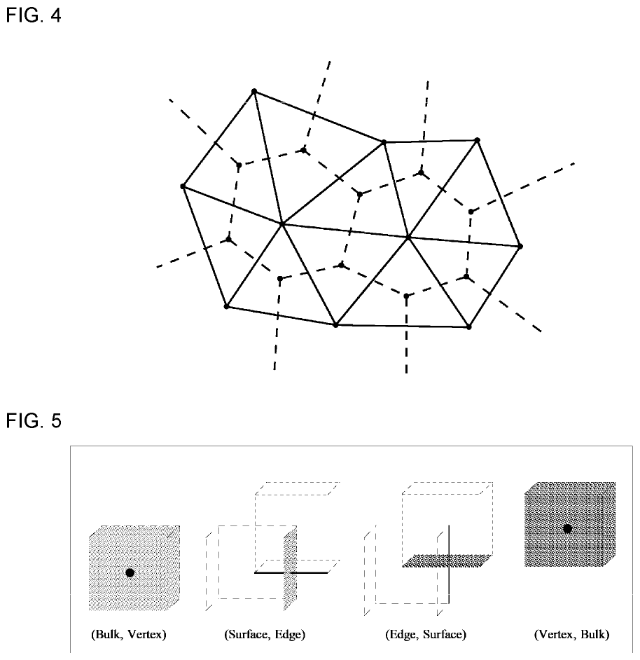

Specifically, the center of a 3-complex (a bulk) of cell complexes (a mesh) is defined, and this is used as a 0-complex (a vertex) of a dual cell complex (a dual mesh). Additionally, the lines connecting the 0-complexes (vertices) of the dual cell complexes (dual mesh) defined as the centers of neighboring cell complexes (the mesh) (which share 2-complexes (surfaces)) is defined as 1-complexes (edges) of the dual cell complexes (the dual mesh). A surface defined by 1-complexes (edges) of the dual cell complexes (the dual mesh) defined in this way is defined as a 2-complex (surface) of the dual cell complex (the dual mesh), and, additionally, a space enclosed by 2-complexes (surfaces) of the dual cell complex (the dual mesh) is defined as a 3-complex (a bulk) of the dual cell complex (dual mesh). FIG. 4 is a diagram illustrating the relationship between the cell complexes and the dual cell complexes. Note that, for convenience in illustration, in FIG. 4 dual cell complexes of two-dimensional polyhedrons (that is, “polygons”) are depicted. In the figure, cell complexes are depicted by the solid lines and dual cell complexes are depicted by the dotted lines.

In this way, with the cell complexes (the mesh) and the dual cell complexes (the dual mesh), a duality exists between the k-complexes and the (n−k)-complexes. Specifically, in the cell complexes (the mesh) and the dual cell complexes (the dual mesh), there is a one-to-one correspondence between the pair of 0-complexes (vertices) and 3-complexes (bulks), the pair of 1-complexes (edges) and 2-complexes (surfaces), the pair of 2-complexes (surfaces) and 1-complexes (edges), and the pair of 3-complexes (bulks) and 0-complexes (vertices). Consequently, an isomorphism ★ (a one-to-one correspondence) can be defined between cell complexes (meshes) and dual cell complexes (dual meshes) (referencing, for example, FIG. 5, described in detail below, as well).

Moreover, the dual cell complexes themselves are complexes. Consequently, boundary homomorphics can be defined also for chains of dual cell complexes.

Note that the discussion above is a pure mathematical technique. On the other hand, because the mathematical technique described above is used for numeric calculations, in the data structure according to the present embodiment, physical quantities are assigned in the dual cell complexes. That is, in the data structure according to the present embodiment, the domain for which numerical calculations are to be conducted is divided by polyhedrons having complex structures, and physical quantities that are used in numeric calculations are assigned to the dual cell complexes relating to the complex structures of the polyhedrons.

Here the physical quantity, in the case of fluid analysis, for example, is a pressure or a flow speed, and in the case of electromagnetic field analysis, is the electromagnetic potential. Note that typically the physical quantity, such as pressure or flow speed, is a continuous value. A physical quantity that is a continuous value is discretized through assignment to the cell complexes and dual cell complexes corresponding to the divisions of the domain over which the numeric calculations are to be performed.

The method for discretizing, described simply, corresponds to discretizing a de Rham complex, where here the continuous version of a de Rham complex will be explained simply. Let M be defined as a differentiable manifold and Ω^{k} (M) be defined as a space of k-order differential forms on M. Note that Ω⁰ (M) is the space of a smooth function on M. An operator called an exterior derivative d^{k} is defined in the k-order differential form, where the chain of the space Ω^{k} (M) of the k-order differential form on M structures a chain complex, and d^{k}d^{k+1}=0.

$$\begin{matrix}[ Formula 2 ] & \\ 0 \to {Ω}^{0} ( M ) \to … \to {Ω}^{k} ( M ) {\to }^{d} {Ω}^{k + 1} ( M ) \to … \to {Ω}^{n} ( M ) \to 0 & \end{matrix}$$

On the other hand, the basic concept of de Rham complex discretization is that the value is determined through integrating the differential forms on the discretized complexes, as described above. In the data structure according to the present embodiment, the object is that of application to numeric calculations, and thus physical quantities are assigned on the dual cell complexes by integrating, on the dual cell complexes, the physical quantities (physical fields) used in numeric calculations. Note that, as can be understood from the nature of a Hodge star, which will be described in detail below, this is equivalent, through duality, to assigning physical quantities on the cell complexes by integrating, on the cell complexes, the physical quantities (physical fields) used in numeric calculations.

Specifically, if σ is the base of the k-dual-cell-complex and ω is a k-order differential form, the value of the discretized differential form is determined by the following equation:

$$\begin{matrix}[ Formula 3 ] & \\ {ω}_{σ} = {\int }_{σ} ω & \end{matrix}$$

For example, a 0-complex is a point, so a 0-differential form can be viewed as a scalar field, and thus a differential form discretized following the definition set forth above would be the value of the scalar field at that point. In the data structure according to the present embodiment, the physical quantities (physical fields) used in numerical calculations are assigned on the dual cell complexes, so in the case of, for example, a pressure distribution in fluid analysis, the pressures are sampled at each of the vertices of the dual cell complexes of that wherein the domain over which the numerical calculations are to be conducted has been divided into cell complexes. When one considers the duality wherein the division of the domain, for which the numerical calculations are to be conducted, is through division into cell complexes (a mesh) and division thereof by dual cell complexes (a dual mesh), this is the same as the divisions of the domain over which the numerical calculations are to be conducted being represented by each of the vortexes of the dual cell complexes for sampling the pressures.

Moreover, a 1-complex is an edge, enabling the 1-differential form to be considered to be a vector field through a musical homomorphic. Thus when sampling the vector field on the edge, the sampling may be through integrating the first-order differential form on the 1-complex (edge) following the definition set forth above. In the data structure according to the present embodiment, in the case of a flow speed distribution in fluid analysis, for example, this engenders sampling of the flow speed along each of the edges of the dual cell complex wherein the domain over which the numerical calculations are to be conducted has been divided into cell complexes.

As already indicated, there is duality between division by cell complexes (a mesh) and division by dual cell complexes (a dual mesh), and, additionally, because this relates also to calculation of numeric values, in the data structure according to the present embodiment control is through pairing of the divisions by cell complexes (a mesh) and divisions by dual cell complexes (a dual mesh). Here “controlling by pairing” refers to having identical, or correlated, indices for each of the complexes.

That is, as illustrated in FIG. 5, control is through pairing a 3-complex (a bulk) in the cell complex with a 0-complex (a point) in the dual cell complex, pairing a 2-complex (a surface) in the cell complex with a 1-complex (an edge) in the dual cell complex, pairing a 1-complex (an edge) in the cell complex with a 2-complex (a surface) in the dual cell complex, and pairing a 0-complex (a point) in the cell complex with a 3-complex (a bulk) in the dual cell complex. This pairing is defined through the isomorphism ★ between cell complexes (a mesh) and dual cell complexes (a dual mesh).

Controlling in this way through pairing the divisions by cell complexes (a mesh) with divisions by dual cell complexes (a dual mesh) to cause the indices to be identical or correlated increases the locality of references in executing a numerical calculation program on a computer, as described below. Moreover, division by dual cell complexes (the dual mesh) has a function that is similar to a staggered grid in structured grids, and thus the use of the data structure stability in the present embodiment makes it possible to numerical calculations with high stability.

In the data structure according to the present embodiment, physical quantities are assigned on the dual cell complexes through integrating, on the dual cell complexes, the physical quantities (physical fields) used in numerical calculations. A large benefit to assigning physical quantities on the dual cell complexes in this way is that many of the properties of the differential forms that are satisfied by the continuous version of de Rham complexes are inherited by the discrete version of de Rham complexes. Consequently, a differential form defined in a discrete version of a de Rham complex may be termed a discrete differential form.

For example, a relational formula similar to Stokes theorem is satisfied:

$$\begin{matrix}[ Formula 4 ] & \\ {\int }_{σ} d ω = {\int }_{\partial 0} ω & \end{matrix}$$

Moreover, the discretized version of the Hodge star operator * is defined as follows using the isomorphism ★ between the cell complexes (the mesh) and the dual cell complexes (the dual mesh):

$$\begin{matrix}[ Formula 5 ] & \\ * \text{:} {Ω}_{d}^{k} ( X ) \to {Ω}_{d}^{n - k} ( ⋆ X ) \\ \frac{1}{\vert {σ}^{k} \vert} {\int }_{{o}^{k}} {α}^{k} = \frac{1}{\vert * {σ}^{k} \vert} {\int }_{⋆ {σ}^{k}} * {α}^{k} & \end{matrix}$$

As is clear from the definitions above, in the discretized Hodge star operator, values in cell complexes (meshes) and values in dual cell complexes (dual meshes) can be converted back and forth.

Moreover, in a differential form, an operator in typical vector analysis can be written using an exterior differential. Given this, the calculation using these differential forms satisfies also a discretized de Rham complex. Gradient grad, divergence div and rotation rot will be explained below.

A gradient grad can be written as below using musical isomorphism #.

$$\begin{matrix}[ Formula 6 ] & \\ grad ( f ) = ∇ f = {( df )}^{\#} & \end{matrix}$$

Divergence div can be written as shown below using musical isomorphism ♭ and the Hodge star operator *:

$$\begin{matrix}[ Formula 7 \text{-} 1 ] & \\ div ( V ) = ∇ \cdot V = * d * {V}^{♭} & \end{matrix}$$

Rotation rot can be written, as below, using musical isomorphisms # and ♭ symbol and the Hodge star operator *:

$$\begin{matrix}[ Formula 7 \text{-} 2 ] & \\ rot ( V ) = ∇ \times V = (* {{dV}^{♭} )}^{\#} & \end{matrix}$$

In addition to that which was illustrated above, in discrete differential forms it is possible to define operators such as the Laplacian, the Lie differential, and the inner product.

As described above, the data structure according to the present embodiment is not limited to a structured grid, but rather a general structured grid, which may be in an unstructured grid, may be used. On the other hand, in the data structure according to the present embodiment the domain for which numerical calculations are to be conducted is divided into cell complexes, and dual cell complexes of the cell complexes are defined. Physical quantities (physical fields) used for the numerical calculations assign physical quantities on the cell complexes and dual cell complexes.

In the data structure according to the present embodiment, all operators used in vector analysis in three-dimensional Euclidean space can be executed through calculation using discrete differential forms. Consequently, the data structure according to the present embodiment can be applied to many numeric calculations. Applications in fluid analysis and electromagnetic field analysis will be explained below as examples of application of the data structure according to the present embodiment.

[Fluid Analysis]

In fluid analysis, the continuity equation and Navier-Stokes equation are used as the governing equations. The continuity equation and the Navier-Stokes equation can be written using differential forms, as shown below:

$$\begin{matrix}[ Formula 8 ] & \\ \frac{\partial }{\partial t} (* ρ ) = - {L}_{{u}^{\#}} , (* ρ ) \\ \frac{\partial }{\partial t} u = - {L}_{{u}^{\#}} * u + \frac{1}{2} dg ( {u}^{\#} , {u}^{\#} ) - \frac{1}{ρ} ( dP - ηΔ u ) & \end{matrix}$$

Here ρ is the mass density within the fluid, *ρ is the dual Hodge thereof, and represents the total mass within the element. The Lie differential in respect to the speed field u^{#} is written as L_{u#}. The metric tensor is g (,), defining u: =g (u^{#},). Pressure P is a function of the mass density ρ. Note that Δ is defined as the Hodge Laplacian, that is, Δ=δ d+d δ, δ=(−1)^{k}*⁻¹d*.

As can be understood from the forms of the equations, above, the continuity equation and the Navier-Stokes equation can be executed as equations on the data structure according to the present embodiment.

[Electromagnetic Field Analysis]

In electromagnetic field analyses, electromagnetic potential is used as the governing equation. Amperes law and Gausses law can be written using the differential forms, given below, if the gauge is fixed using a Lorentz gauge.

$$\begin{matrix}[ Formula 9 ] & \\ * d * A + ɛ µ \frac{\partial ϕ}{\partial t} = 0 \\ ( ɛμ \frac{{\partial }^{2}}{\partial {t}^{2}} - Δ ) Λ = μ * j \\ ( ɛµ \frac{{\partial }^{2}}{\partial {t}^{2}} - Δ ) ϕ = \frac{1}{ɛ} * ρ & \end{matrix}$$

Here A is a vector potential, φ is a scalar potential, J is the current density, and ρ is the electric charge. As can be understood from the forms of the equations, above, for the electromagnetic potential, the calculations can be carried out on the data structure according to the present embodiment.

As described above, the data structure according to the present embodiment can be applied to many different numeric calculations. Numeric calculations according to the present embodiment, and execution of a numerical calculation program on a computer, will be explained below.

[Structure of the Device]

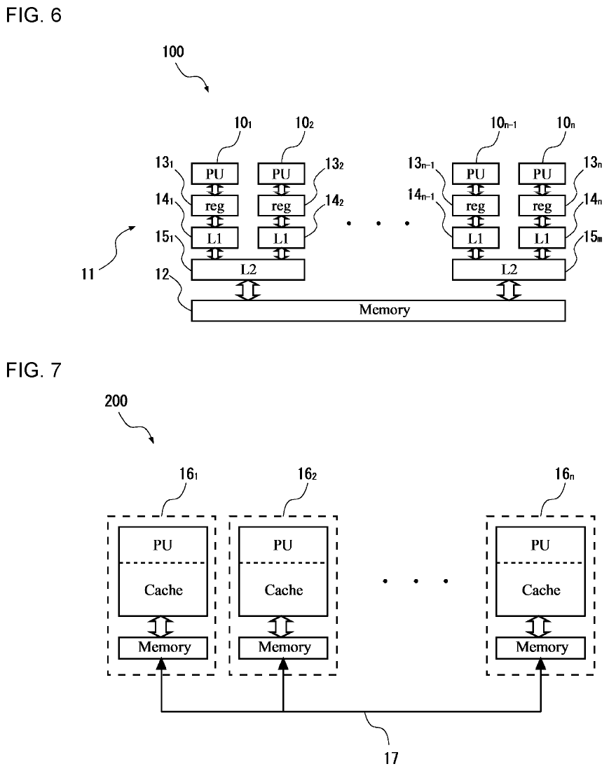

FIG. 6 is a diagram depicting the concept of a hierarchy of a shared memory, and FIG. 7 is a diagram depicting the concept of a hierarchy of a distributed memory. The numerical calculation method and numerical calculation program according to an embodiment according to the present disclosure can be applied suitably in a computer having a plurality of computing units and hierarchical storage units for storing data used in the calculations thereof. Given this, the calculation process in the computer that is equipped with the plurality of computing units and the hierarchical storage unit will be explained in reference to FIG. 6 and FIG. 7. Note that a computer equipped with a plurality of computing units is called “parallel computer,” and the calculation processes on a parallel computer are called parallel processing or parallel computing.

A parallel computer 100 that includes a plurality of computing units 10₁ through 10ₙ, and hierarchical storage units 11 for storing data that is used in the calculations thereof, will be described in the conceptual diagram depicted in FIG. 6. The hierarchical storage unit 11 has storage units arranged hierarchically within each computing unit 10₁ through 10ₙ and a main storage unit 12. In the example depicted in FIG. 1, there is a structure of registers 13₁ through 13ₙ, L1 cache memories 14₁ through 14ₙ, L2 cache memories 15₁ through 15ₘ, and a main storage unit 12, sequentially from the computing units 10₁ through 10ₙ. Note that the structure depicted in FIG. 6 is just one example, where the structure of the hierarchical storage unit 11 is not limited thereto, that rather in relation to the hierarchy, there are modified examples such as inserting L3 cache memories between the L2 cache memories 15₁ through 15ₘ and the main storage unit 12.

The processing speeds of these storage units are sequentially higher speeds for the main storage unit 12, the L2 cache memories 15₁ through 15ₘ, the L1 cache memories 14₁ through 14ₙ and the registers 13₁ through 13ₙ, and the memory bandwidths, which are the abilities of the memories to transfer data, are lower than the calculation performance of the computing units 10₁ through 10ₙ (bytes per flop is low). This is important to cause the high reference locality from such characteristics to be reflected into the calculation performance.

Note that a state wherein there is high reference locality is a state wherein there is a high likelihood that data that has been referenced will be referenced again, or that data that has an address near that data will be referenced. In other words, it is a state wherein calculations are carried out by the computing units 10₁ through 10ₙ using data stored in higher-level storage units such as the registers 13₁ through 13ₙ or the L1 cache memories 14₁ through 14ₙ, or the L2 cache memories 15₁ through 15ₘ, or the like.

In other words, a strategy for reducing the situations wherein the computing units 10₁ through 10ₙ use data that is stored in the main storage unit 12 is required. For example, such a situation occurs when a computing unit 10ₙ must perform a calculation using a result calculated by a computing unit 10₁. Moreover, if the computing unit 10ₙ must perform a calculation using a result calculated by the computing unit 10₁, the calculation by the computing unit 10ₙ cannot start until the calculation by the computing unit 10₁ has been completed, which also produces a problem of causing latency.

FIG. 7 is a diagram illustrating the concept of a hierarchy of a distributed memory, which is employed in large computer systems, and the like. In the parallel computer 200, illustrated in FIG. 7, nodes 16₁ through 16ₙ are equipped with pluralities of computing units and hierarchical storage units for storing data used in the calculations thereby, and, additionally, the main storage units 12₁ through 12ₙ in each of the nodes 16₁ through 16ₙ are mutually shared over a network 17. Here the sharing of the main storage units 12₁ through 12ₙ refers to the ability of the computing units of each of the nodes 16₁ through 16ₙ to mutually reference the data stored in the main storage units 12₁ through 12ₙ through applying unique addresses to the main storage units 12₁ through 12ₙ.

Even in a computer of a structure such as described above, increasing the reference locality is important in order to produce good calculation performance. In particular, it is important to minimize the states wherein the computing unit of a given node 16₁ through 16ₘ references data stored in a main storage unit 12₁ through 12ₙ and of a different node 16₁ through 16ₘ.

From the point of view described above, in the computer architecture that is dominant today there is the need for numerical calculation methods and numerical calculation programs with high reference locality. Given this, the numerical calculation method and numerical calculation program according to an embodiment according to the present disclosure carries out numeric calculations using an explicit method. This “explicit method” will be described below.

[Explicit Method]

An explicit method is a method wherein a state quantity of a position x at a second time t+Δ t, which is slightly later, is calculated from only the state quantity at a first time t. On the other hand, an implicit method is a method that uses a state quantity of another position xᵢ at the second time t+Δ t in order to calculate the state quantity at the position x at the second time t+Δ t. In short, this means that in an implicit method it is necessary to solve a system of equations that includes a state quantity at another position x₁ at the second time t+Δ t in order to calculate the state quantity at the position x at the second time t+Δ t, whereas in an explicit method it is not necessary to solve such a system of equations.

In this way, in an explicit method it is not necessary to solve a system of equations, and thus the calculation overhead and the memory transfer overhead, at each time step, are small. Moreover, if in order to calculate the state quantity at the position x at the second time t+Δ t, the calculation is based on state quantities of only the neighborhood of the position x at the first time t, the reference locality will be even higher. Given this, the conditions for being able to apply an explicit method with a high level of reference locality will be explained below.

Basically, the time evolution in a field φ (n, t) of a given domain, as depicted in Equation (1), below, may be expressed as a function f of a first-order differential φ′ (n, t) and a second-order differential φ″ (n, t) relating to the field φ (n, t) and of a space of the field. Note that the location is n and the time is t.

$$\begin{matrix}[ Formula 10 ] & \\ \frac{\partial ϕ ( n , t )}{\partial t} = f ( ϕ ( n , t ) , {ϕ}^{′} ( n , t ) , {ϕ}^{″} ( n , t ) ) & ( 1 )\end{matrix}$$

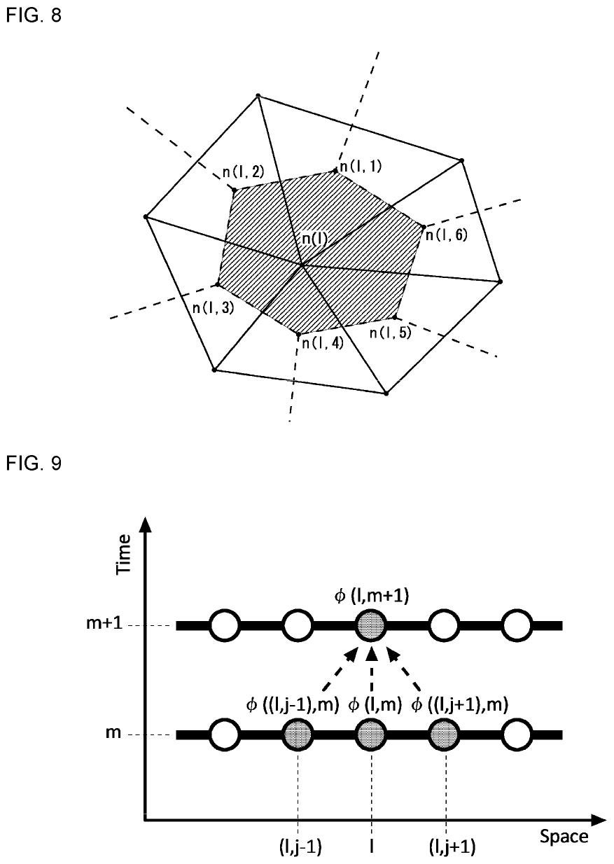

The field φ (n, t), expressed as in the equation above, is discretized in respect to time and each individual complex. Discretizing the time t uses the index m to produce t (m+1)=t (m)+Δ t. On the other hand, discretizing the location n uses the index l of each complex to produce n (l). Given this, the vertex n (l, j) in the neighborhood of the vertex n (l) that corresponds to the index l of each complex can be expressed as in FIG. 8, for example. Note that while in FIG. 8 a two-dimensional version is presented, for ease in illustration, the surroundings can be expressed similarly in three dimensions as well. Moreover, while here the indices of the vertex n (l, j) for the neighborhood of the vertex n (l) corresponding to the index l uses (l, j), this is for ease in illustration, and does not mean that the indices for a dual cell complex are two variables. This means that control is by causing the indices for the divisions of the cell complexes (the mesh) and the divisions of the dual cell complexes (the dual mesh) to be identical or correlated.

As illustrated in FIG. 8, the vertex n (l, j) of a dual cell complex exists in the neighborhood of the vertex n (l) of a cell complex. Given this, the vertex n (l, j) of the dual cell complex can be calculated as follows. The dual ★ n (l) of the vertex n (l) of the cell complex is calculated first. This ★ is the isomorphism described above. Note that ★ n (l) is the domain illustrated by the slanted lines in FIG. 8. Additionally, the vertex n (l, j) of the dual cell complex that is in the neighborhood of the vertex n (l) of the cell complex is an element of ∂ (★ n (l)) that uses a boundary homomorphic ∂.

Here the isomorphism ★ and the boundary homomorphic ∂ may be used for the neighborhood vertex n (l, j) from the vertex n (l). Additionally, as described above, in the data structure according to the present embodiment, control is by pairing the division by cell complexes (the mesh) and the division by dual cell complexes (the dual mesh) using the isomorphism ★, and the data assigned to the vertex n (l) and the vertex n (l, j) is stored in a nearby location in the memory on the computer. In this way, the numerical calculation program that uses the data structure of the present embodiment carries out control by pairing the divisions by the cell complexes (the mesh) and the divisions by the dual cell complexes (the dual mesh), to achieve, in execution on the computer, a data arrangement that has high reference locality.

Additionally, the first-order differential φ′ (n (l), t (m)) and the second order differential φ″ (n (l), t (m)) of the field, using the neighborhood, can be approximated by a function of the field φ (n (l, j), t (m)) at the vertex n (l, j) of the dual cell complex in the neighborhood. Consequently, f (φ (n, t), φ′ (n, t), φ″ (n, t)) can be approximated as F (φ (n (l, j), t (m))).

The result is that the equation above can be expressed as follows:

$$\begin{matrix}[ Formula 11 ] & \\ ϕ ( n ( l ) , t ( m + 1 ) ) = ϕ ( n ( l ) , t ( m ) ) + F ( ϕ ) ( n ( l , j ) , t ( m ) ) Δ t & \end{matrix}$$

Moreover, if the equation above is expressed using the indices (l, m), it can be expressed as follows:

$$\begin{matrix}[ Formula 12 ] & \\ ϕ ( l , m + 1 ) = ϕ ( l , m ) + F ( ϕ ( ( l , j ) , m ) ) Δ t & \end{matrix}$$

As can be understood from the equation above, φ (l, m+1) is determined by φ (l, m) and φ ((l, j), m). What is important here is that the right-hand side of the equation above does not include m+1. This means that it is possible to calculate the state quantity of the vertex n (l) at the second time t (m+1) at a time slightly later from only the state quantity at the first time t (m).

Additionally, while the right-hand side of the equation above includes the indices (l, j), the vertex of the dual cell complex that is near to the vertex n (l) of the complex is expressed by n (l, j), and thus φ ((l, j), m) is the value of the field φ at the vertex that is near to the vertex n (l) at the first time t (m). FIG. 9 is a diagram depicting the detail of an explicit method that has high reference locality. This means that, in the equation shown above, φ (l, m) of index l at the location at the time of index m, and φ ((l, j), m) at the index (l, j) that is in the neighborhood thereof may be used in calculating φ (l, m+1) at the position index l at the time of index m+1, as depicted in FIG. 9. The index l corresponds to the nearness of the address when storing the value of φ in memory, and thus when calculating φ (l, m+1), data with high reference locality, that being φ (l, m) and φ ((l, j), m), are used.

As can be understood from the discussion above, when expression such as in Equation (1), above, is possible, it is possible to use an explicit method with high reference locality. Moreover, even if an arbitrarily high-order differential regarding the space of the field is included in the right-hand side of Equation (1), above, this method can be used in the same way. Additionally, the Navier-Stokes equation, and the electromagnetic potential equation, described above, can be expressed as in Equation (1), above. Consequently, an explicit method with high reference locality can be used when performing numeric calculations of physical quantities at a second time, slightly later, from a physical quantity at a first time, said quantity being stored in the hierarchical storage unit, using a computer that has a plurality of computing units and hierarchical storage units for storing data used in the calculations by the computing units.

That is, the numerical calculation program according to the embodiment of the present disclosure is well-suited for controlling a parallel computer of a shared memory type, as depicted in FIG. 6, and the numerical calculation method according to an embodiment according to the present disclosure is well-suited as a process in a parallel computer of a shared memory type, as depicted in FIG. 7. Moreover, obviously the numerical calculation method and numerical calculation program according to the embodiment of the present disclosure is effective even on a parallel computer of a shared memory type wherein each node in a parallel computer of a distributed memory type is structured as a parallel computer of a shared memory type.

While the present disclosure was explained based on an embodiment while referencing the drawings, the present disclosure is not limited by the embodiments described above. The numerical calculation method explained above can be packaged as a numerical calculation program, and, conversely, execution of the numerical calculation program, explained above, can be viewed as execution of the numerical calculation method. The numerical calculation program described above can be embodied by, for example, production, or the like, of a state wherein it is recorded on a computer readable non-transient media.

### EXPLANATION OF REFERENCE SYMBOLS

100, 200: Parallel Computers
10₁ through 10ₙ: Computing units
11: Hierarchical storage unit
12: Main Storage unit
13₁ through 13ₙ: Registers
14₁ through 14ₙ: L1 Cache Memories
15₁ through 15ₘ: L2 Cache Memories
16₁ through 16ₙ: Nodes
17: Network

1-13. (canceled)

14. A system for calculating a shape and a plurality of physical quantities, the system comprising:
a hierarchical storage; and
processor circuitry that couples to the hierarchical storage and is configured to:
divide, into cell complexes and dual cell complexes, a domain for which calculations are to be conducted, to correspond to the shape;
assign the plurality of physical quantities to the cell complexes and the dual cell complexes; and
reference data stored in the hierarchical storage by using a Hodge star operator and a boundary homomorphic that are defined for the cell complexes and dual cell complexes.

15. The system of claim 14, wherein the processor circuitry is further configured to:
communize or correlate indices used in the calculations by pairing k-cell-complexes of the cell complexes and (n−k)-dual-cell complexes of the dual cell complexes.

16. The system of claim 15, wherein the processor circuitry is further configured to:
store, in the hierarchical storage, only data of first physical quantities of the physical quantities, wherein the first physical quantities are assigned to the cell complexes or to the dual cell complexes is stored; and
conduct conversion by a Hodge star operator when referencing data of second physical quantities of the plurality of physical quantities, wherein the second physical quantities are assigned to the other of the cell complexes and of the dual cell complexes.

17. A method for numerical calculations, comprising:
dividing, into cell complexes and dual cell complexes, a domain for which calculations are to be conducted;
assigning physical quantities to the cell complexes and the dual cell complexes;
referencing data stored in a storage by using a Hodge star operator and a boundary homomorphic that are defined for the cell complexes and dual cell complexes; and
conducting the calculations by using an equation in a differential form on the cell complexes and the dual cell complexes, wherein the equation is an equation into which a governing equation used in the numerical calculations is converted.

18. The method of claim 17, wherein:
the equation in the differential form expresses a time evolution of a field using a field and a first order space differential and a higher-order differential, of order two or above, of the field.

19. The method of claim 17, further comprising:
approximating the equation in the differential form, using a value of the equation in the neighborhood, calculated using duality between the cell complexes and the dual cell complexes.

20. The method of claim 17, wherein:
the equation in the differential form is expressed in Formula 1 using a function F, wherein φ is a field, m is a discretized index of time, l is an index of a cell complex or a dual cell complex, and (l, j) are indices indicating a cell complex or dual cell complex in the domain of the cell complex or dual cell complex of the index of l:
$$\begin{matrix}[ Formula 1 ] & \\ ϕ ( l , m + 1 ) = ϕ ( l , m ) + F ( ϕ ( ( i , j ) , m ) ) Δ t & \end{matrix}$$

21. A non-transitory computer-readable medium having one or more executable instructions stored thereon, which, when executed by processor circuitry, cause the processor circuitry to conduct a method for numerical calculations related to a shape and a plurality of physical quantities, the method comprising:
dividing, into cell complexes and dual cell complexes, a domain for which numerical calculations are to be conducted, to correspond to the shape;
assigning the physical quantities to the cell complexes and the dual cell complexes;
storing, in a hierarchical storage, the assigned physical quantities;
referencing data stored in the hierarchical storage by using a Hodge star operator and a boundary homomorphic that are defined for the cell complexes and dual cell complexes; and
conducting the calculations related to the shape and the plurality of physical quantities by using an equation in a differential form on the cell complexes and the dual cell complexes, wherein the equation is an equation into which a governing equation used in the numerical calculations is converted.

22. The non-transitory computer-readable medium of claim 21, wherein the method further comprises:
converting the physical quantities stored in the hierarchical storage by a Hodge star operator.

23. The non-transitory computer-readable medium of claim 21, wherein the method further comprises:
parallel processing equations of differential forms on the cell complexes and the dual cell complexes through assignment of the equations to respective calculating devices.

24. The non-transitory computer-readable medium of claim 21, wherein
the equation in the differential form expresses a time evolution using the field and a first order space differential and a higher-order differential, of order two or above, of the field.

25. The non-transitory computer-readable medium of claim 21, wherein the method further comprises:
approximating the equation in the differential form, using a value of the equation in the neighborhood, calculated using duality between the cell complexes and the dual cell complexes.

26. The non-transitory computer-readable medium of claim 21, wherein:
the equation in the differential form is expressed in Formula 2 using a function F, wherein φ is a field, m is a discretized index of time, l is an index of a cell complex or a dual cell complex, and (l, j) are indices indicating a cell complex or dual cell complex in the neighborhood of cell complex or dual cell complex of the index of l.
$$\begin{matrix}[ Formula 2 ] & \\ ϕ ( l , m + 1 ) = ϕ ( l , m ) + F ( ϕ ( ( l , j ) , m ) ) Δ t & \end{matrix}$$
